(19) United States
(12) Patent Application Publication
(10) Pub. No.: US 2026/0100341 A1
(43) Pub. Date: Apr. 9, 2026

(54) Sheath and Temperature Control of Process Kit

(71) Applicant: Applied Materials, Inc., Santa Clara, CA (US)

(72) Inventors: Jaeyong CHO, San Jose, CA (US); Kartik RAMASWAMY, San Jose, CA (US); Daniel Sang BYUN, Campbell, CA (US); Tianhong WANG, Sunnyvale, CA (US); Kenneth SCHATZ, Los Altos, CA (US); Kiril KIRKOV, San Francisco, CA (US); Stephen Donald PROUTY, San Jose, CA (US); Reyn Tetsuro WAKABAYASHI, San Jose, CA (US); Yoel JW PARK, Cupertino, CA (US); Jianqiu HUANG, Fremont, CA (US); Arkadeep KUMAR, Milpitas, CA (US); Benjamin Michael STOVER, San Jose, CA (US); Carlaton WONG, Sunnyvale, CA (US)

(21) Appl. No.: 18/910,783

(22) Filed: Oct. 9, 2024

(51) Int. Cl. H01J 37/32

(52) U.S. Cl. CPC H01J 37/32724; H01J 37/32568; H01J 2237/002; H01J 2237/2007

(57) ABSTRACT

Embodiments of substrate supports are provided herein. In some embodiments, a substrate support includes: a ceramic plate having a first side configured to support a substrate and a second side, wherein the ceramic plate includes an electrode embedded in the ceramic plate; a first cooling plate coupled to the second side of the ceramic plate; a ceramic ring disposed about the ceramic plate and having a first side and a second side, wherein the ceramic ring includes one or more chucking electrodes and a heating element disposed in the ceramic ring, wherein the ceramic ring is spaced apart from the ceramic plate and the first cooling plate; a second cooling plate coupled to the second side of the ceramic ring, wherein the second cooling plate is thermally isolated from the first cooling plate; and a sealing element disposed adjacent to the ceramic ring and the ceramic plate.

### FIELD

Embodiments of the present disclosure generally relate to substrate processing systems, and more specifically, to process kits for use in substrate processing systems.

### BACKGROUND

Radio frequency (RF) power is often used in etching processes, for example, requiring very high aspect ratio holes to make contacts or deep trenches for laying infrastructure for electrical pathways. RF power can be used for plasma generation and/or for creating bias voltage on a substrate being processed to attract ions from bulk plasma. An electrostatic chuck is used to electrostatically hold a substrate to control substrate temperature during processing. The electrostatic chuck typically includes an electrode embedded in a dielectric plate and a cooling plate disposed below the dielectric plate. A process kit can include an edge ring that is often disposed above the cooling plate and about the dielectric plate to guide a substrate.

However, when a substrate is placed in a processing chamber after long idle time, a temperature of the edge ring goes up as substrates are processed with two different RF powers. A temperature differential between the edge ring and the dielectric plate may cause a non-uniform chemical reaction between the edge ring and process gases as compared to the dielectric plate and process gases, causing process drift. An RF power source for creating bias is applied to the cooling plate. The inventors have observed that as a height of the edge ring comes down due to ion bombardment during substrate processing, equipotential lines in a sheath created by the bias RF power source become tilted proximate the edge ring and chemical reactions between the edge ring and process gases around the peripheral regions of the substrate cause process drift.

Accordingly, the inventors have provided embodiments of improved process kits.

### SUMMARY

Embodiments of substrate supports are provided herein. In some embodiments, a substrate support includes: a ceramic plate having a first side configured to support a substrate and a second side opposite the first side, wherein the ceramic plate includes an electrode embedded in the ceramic plate; a first cooling plate coupled to the second side of the ceramic plate; a ceramic ring disposed about the ceramic plate and having a first side and a second side opposite the first side, wherein the ceramic ring includes one or more chucking electrodes and a heating element disposed in the ceramic ring, wherein the ceramic ring is spaced apart from the ceramic plate and the first cooling plate; a second cooling plate coupled to the second side of the ceramic ring, wherein the second cooling plate is thermally isolated from the first cooling plate, wherein the first cooling plate and the second cooling plate include coolant channels configured to circulate a coolant; and a sealing element disposed adjacent to the ceramic ring and the ceramic plate.

In some embodiments, a substrate support includes: a ceramic plate having a first side configured to support a substrate and a second side opposite the first side, wherein the ceramic plate includes an electrode embedded in the ceramic plate; a first cooling plate coupled to the second side of the ceramic plate; a ceramic ring disposed about the ceramic plate and having a first side and a second side opposite the first side, wherein the ceramic ring includes one or more chucking electrodes and a heating element disposed in the ceramic ring, wherein the ceramic ring is spaced apart from the ceramic plate and the first cooling plate; a second cooling plate coupled to the second side of the ceramic ring, wherein the second cooling plate is thermally isolated from the first cooling plate, wherein the first cooling plate and the second cooling plate include coolant channels configured to circulate a coolant; one or more sealing elements disposed adjacent to: the ceramic ring and the second cooling plate; and the ceramic ring and the ceramic plate; and an edge ring disposed on the ceramic ring and a thermal pad disposed between the edge ring and the ceramic ring.

In some embodiments, a process chamber includes: a chamber body having a substrate support disposed within an inner volume of the chamber body, wherein the substrate support includes a ceramic plate having a first side configured to support a substrate and a second side opposite the first side, wherein the ceramic plate includes an electrode embedded in the ceramic plate; a first cooling plate coupled to the second side of the ceramic plate; a ceramic ring disposed about the ceramic plate and having a first side and a second side opposite the first side, wherein the ceramic ring includes one or more chucking electrodes and a heating element disposed in the ceramic ring, wherein the ceramic ring is spaced apart from the ceramic plate and the first cooling plate; a second cooling plate coupled to the second side of the ceramic ring, wherein the second cooling plate is thermally isolated from the first cooling plate, wherein the first cooling plate and the second cooling plate include coolant channels configured to circulate a coolant; and a sealing element disposed adjacent to the ceramic ring and the ceramic plate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic side view of a process chamber having a substrate support in accordance with at least some embodiments of the present disclosure.

FIG. 2 depicts a schematic partial side view of a substrate support in accordance with at least some embodiments of the present disclosure.

FIG. 3 depicts a schematic cross-sectional side view of a ceramic ring in accordance with at least some embodiments of the present disclosure.

FIG. 4 depicts a schematic partial side view of a substrate support in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of substrate supports and process kits for use in a substrate processing chamber are provided herein. The substrate support includes a ceramic plate having a support surface to support a substrate. The substrate support includes a process kit having a ceramic ring disposed about the ceramic plate. The process kit further includes an edge ring disposed on the ceramic ring to guide the substrate. The ceramic ring and the ceramic plate are advantageously thermally isolated from each other to provide independent temperature control. Also, the substrate support extends RF power to the ceramic ring, extending an electric field beyond the edge of the substrate, improving uniformity and performance at the edge of the substrate. Thermal layers disposed between various components of the substrate support advantageously facilitate or prevent heat transfer to provide temperature control across the substate support.

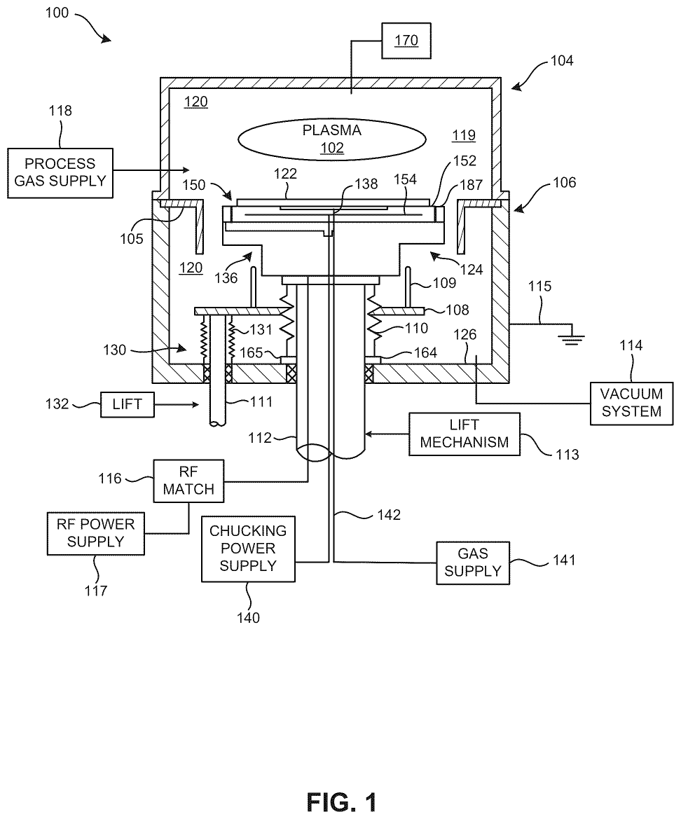

FIG. 1 depicts a schematic side view of a process chamber (e.g., a plasma processing chamber) having a substrate support in accordance with at least some embodiments of the present disclosure. In some embodiments, the plasma processing chamber is an etch processing chamber. However, other types of processing chambers configured for different processes can also use or be modified for use with embodiments of the electrostatic chuck described herein.

The chamber 100 is a vacuum chamber which is suitably adapted to maintain sub-atmospheric pressures within a chamber interior volume 120 during substrate processing. The chamber 100 includes a chamber body 106 covered by a lid 104 which encloses a processing volume 119 located in the upper half of chamber interior volume 120. The chamber 100 may also include one or more shields 105 circumscribing various chamber components to prevent unwanted reaction between such components and ionized process material. The chamber body 106 and lid 104 may be made of metal, such as aluminum. The chamber body 106 may be grounded via a coupling to ground 115.

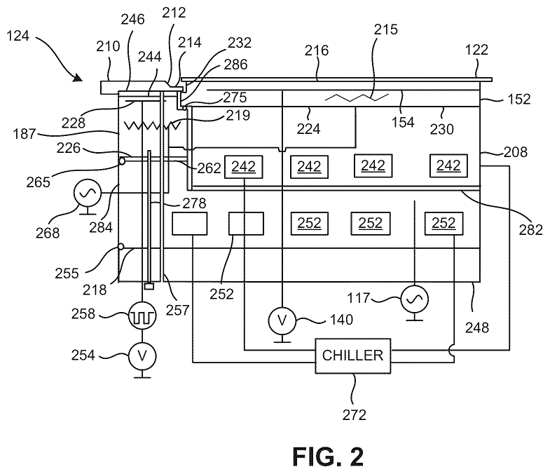

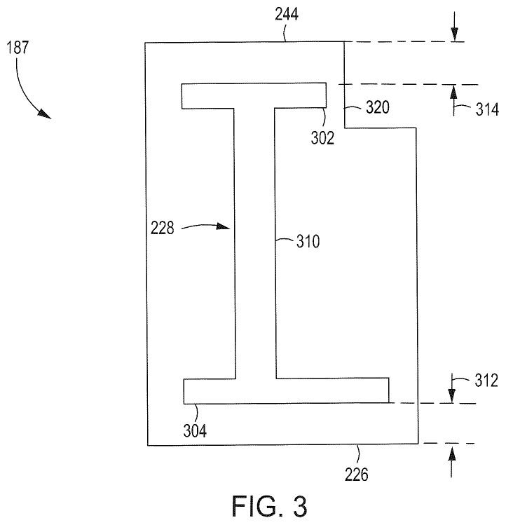

A substrate support 124 is disposed within the chamber interior volume 120 to support and retain a substrate 122, such as a semiconductor wafer, for example, or other such substrate as may be electrostatically retained. The substrate support 124 may generally comprise an electrostatic chuck 150 (described in more detail below with respect to FIGS. 2-3) and a hollow support shaft 112 for supporting the electrostatic chuck 150. The electrostatic chuck 150 comprises a ceramic plate 152 having one or more electrodes 154 disposed therein and a cooling plate 136. The hollow support shaft 112 provides a conduit to provide, for example, backside gases, process gases, fluids, coolants, power, or the like, to the electrostatic chuck 150. The substrate support 124 includes a ceramic ring 187 (described in more detail below with respect to FIGS. 2-3) disposed about the ceramic plate 152.

In some embodiments, the hollow support shaft 112 is coupled to a lift mechanism 113, such as an actuator or motor, which provides vertical movement of the electrostatic chuck 150 between an upper, processing position (as shown in FIG. 1) and a lower, transfer position (not shown). A bellows assembly 110 is disposed about the hollow support shaft 112 and is coupled between the electrostatic chuck 150 and a bottom surface 126 of chamber 100 to provide a flexible seal that allows vertical motion of the electrostatic chuck 150 while preventing loss of vacuum from within the chamber 100. The bellows assembly 110 also includes a lower bellows flange 164 in contact with an o-ring 165 or other suitable sealing element which contacts the bottom surface 126 to help prevent loss of chamber vacuum.

The hollow support shaft 112 provides a conduit for coupling a backside gas supply 141, a chucking power supply 140, and RF sources (e.g., RF plasma power supply 170 and a bias power supply 117) to the electrostatic chuck 150. In some embodiments, RF energy supplied by the RF plasma power supply 170 may have a frequency of about 40 MHz or greater. The backside gas supply 141 is disposed outside of the chamber body 106 and supplies heat transfer gas to the electrostatic chuck 150. In some embodiments, a RF plasma power supply 170 and a bias power supply 117 are coupled to the electrostatic chuck 150 via respective RF match networks (only RF match network 116 shown). In some embodiments, the substrate support 124 may alternatively include AC, DC, or RF bias power.

A substrate lift 130 can include lift pins 109 mounted on a platform 108 connected to a shaft 111 which is coupled to a second lift mechanism 132 for raising and lowering the substrate lift 130 so that the substrate 122 may be placed on or removed from the electrostatic chuck 150. The electrostatic chuck 150 may include through holes to receive the lift pins 109. A bellows assembly 131 is coupled between the substrate lift 130 and bottom surface 126 to provide a flexible seal which maintains the chamber vacuum during vertical motion of the substrate lift 130.

In some embodiments, the electrostatic chuck 150 includes gas distribution channels 138 extending from a lower surface of the electrostatic chuck 150 (e.g., bottom surface of the cooling plate 136) to various openings in an upper surface of the electrostatic chuck 150 or lower surface of the ceramic ring 187. The gas distribution channels 138 are configured to provide backside gas, such as nitrogen (N) or helium (He), to the top surface of the electrostatic chuck 150 or lower surface of the ceramic ring 187 to act as a heat transfer medium. The gas distribution channels 138 are in fluid communication with the backside gas supply 141 via gas conduit 142 to control the temperature and/or temperature profile of the electrostatic chuck 150 during use.

The chamber 100 is coupled to and in fluid communication with a vacuum system 114 which includes a throttle valve (not shown) and vacuum pump (not shown) which are used to exhaust the chamber 100. The pressure inside the chamber 100 may be regulated by adjusting the throttle valve and/or vacuum pump. The chamber 100 is also coupled to and in fluid communication with a process gas supply 118 which may supply one or more process gases to the chamber 100 for processing a substrate disposed therein.

In operation, for example, a plasma 102 may be created in the chamber interior volume 120 to perform one or more processes. The plasma 102 may be created by coupling power from a plasma power source (e.g., RF plasma power supply 170) to a process gas via one or more electrodes near or within the chamber interior volume 120 to ignite the process gas and creating the plasma 102. A bias power may also be provided from a bias power supply (e.g., bias power supply 117) to the one or more electrodes 154 within the electrostatic chuck 150 to attract ions from the plasma towards the substrate 122.

FIG. 2 depicts a schematic partial side view of a substrate support 124 in accordance with at least some embodiments of the present disclosure. The ceramic plate 152 includes a first side 216 configured to support a substrate 122 and a second side 224 opposite the first side 216. The ceramic plate 152 includes one or more electrodes 154 embedded therein. In some embodiments, the one or more electrodes 154 comprise an upper electrode, a lower electrode, and a plurality of posts electrically coupled to the upper and lower electrodes. In some embodiments, the ceramic plate 152 includes a heater 215 disposed therein to control a temperature of the ceramic plate 152. In some embodiments, the ceramic plate 152 is made of aluminum nitride (AlN) or aluminum oxide (Al₂O₃). In some embodiments, the ceramic plate 152 includes an annular ring 286 extending radially outward from an outer sidewall 232 of the ceramic plate 152. In some embodiments, an o-ring 275 is disposed adjacent the annular ring 286 and the ceramic ring 187. In some embodiments, the o-ring 275 is disposed between the annular ring 286 and the ceramic ring 187. The o-ring 275 is generally disposed above (e.g., vertically above) the bonding layer 262.

In some embodiments, the cooling plate 136 is made of an electrically conductive material, for example, aluminum (AI). In some embodiments, the cooling plate 136 includes a first cooling plate 208 coupled to the second side 224 of the ceramic plate 152. The first cooling plate 208 includes a plurality of first coolant channels 242. The first coolant channels 242 are configured to flow a coolant therethrough to cool the ceramic plate 152. In some embodiments, the o-ring 275, or sealing element, is disposed along a lower surface of the annular ring 286 to reduce or prevent plasma exposure within a gap between the first cooling plate 208 and the ceramic ring 187 during processing.

In some embodiments, a bonding layer 230 is disposed between the ceramic plate 152 and the first cooling plate 208. In some embodiments, the bonding layer 230 may be a thermal pad configured to provide improved thermal coupling between the first cooling plate 208 and the ceramic plate 152. In some embodiments, the bonding layer 230 comprises silicone. In some embodiments, the bonding layer 230 has a thickness of about 0.1 mm to about 0.4 mm. In some embodiments, the bonding layer 230 has a thermal conductivity of about 0.2 W/mK to about 1.2 W/mk.

A ceramic ring 187 is disposed about the ceramic plate 152. The ceramic ring 187 includes a first side 244 and a second side 226 opposite the first side 244. In some embodiments, the first side 244 is an upper side. In some embodiments, the ceramic ring 187 includes one or more chucking electrodes 228 embedded therein. An edge ring 210 is disposed on the ceramic ring 187. In some embodiments, an outer diameter of the edge ring 210 is greater than an outer diameter of the ceramic ring 187. The edge ring 210 includes an angled inner surface 212 disposed between an uppermost surface of the edge ring 210 and a second upper surface 214.

In some embodiments, the one or more chucking electrodes 228 are coupled to a chucking power supply 254 to hold the edge ring 210. In some embodiments, the one or more chucking electrodes 228 are electrically coupled to the second cooling plate 218 and use the bias power supply 117 to hold or chuck the edge ring 210. In some embodiments, the ceramic ring 187 is made of aluminum nitride (AlN) or aluminum oxide (Al₂O₃). In some embodiments, a thermal pad 246 is disposed between the edge ring 210 and the ceramic ring 187 to promote heat transfer. In some embodiments, the thermal pad 246 is a silicon-based pad. In some embodiments, the gas distribution channels 138 include a first gas channel 257 that extends from a bottom surface of the second cooling plate 218 to a top surface of the ceramic ring 187. The first gas channel 257 may be used to provide backside gas to the ceramic ring 187 to promote independent temperature control of the ceramic ring 187.

In some embodiments, the bias power supply 117 is electrically coupled to the cooling plate 136 to create a same bias voltage on the substrate 122 and the edge ring 210. In operation, the bias power supply 117 applied on the cooling plate 136 creates a sheath in between the substrate 122 and the plasma 102. As a result, ions from the plasma 102 are attracted to the substrate 122 that is biased, and the ions accelerate through the sheath perpendicular to equipotential lines within the sheath. When the edge ring 210 erodes over time due to processing, a shape of the sheath bends proximate an edge of the substrate 122 leading to non-uniform processing of the substrate 122.

For a minimum impact on the substrate 122 and direct voltage control, the bias power supply 117 is advantageously configured to provide a negative pulsed DC power source 258 to the one or more chucking electrodes 228. The negative pulsed DC power source 258 is configured to provide a power profile to correct sheath bending and maintain a substantially flat sheath profile across the substrate 122. In some embodiments, the one or more chucking electrodes 228 are disposed less than 0.4 mm from a bottom of the edge ring 210 to provide efficient coupling of the negative pulsed DC power to the edge ring 210.

The ceramic ring 187 includes a heating element 219 embedded in the ceramic ring 187. The heating element 219 is coupled to a power source 268 (e.g., an AC power source) to heat the heating element 219. In some embodiments, a temperature probe is disposed on the second side 226 of the ceramic ring 187 to monitor and control a temperature of the ceramic ring 187 by controlling the power applied to the heating element 219 by the power source 268. In some embodiments, the chucking electrode is disposed between the first side 244 and the heating element 219. The ceramic ring 187 is spaced apart from the ceramic plate 152. In some embodiments, the ceramic ring 187 is spaced apart from the first cooling plate 208. In some embodiments, the ceramic ring 187 includes a first notch at an upper interior edge. In some embodiments, the annular ring 286 is disposed in the first notch. In some embodiments, the ceramic ring 187 includes a second notch at an upper interior edge. The edge ring 210 may extend into the second notch.

A second cooling plate 218 is coupled to the second side 226 of the ceramic ring 187. In some embodiments, the second cooling plate 218 is electrically connected but thermally isolated from the first cooling plate 208. The second cooling plate 218 a plurality of second coolant channels 252. The second coolant channels 252 are configured to flow a coolant therethrough to cool the ceramic ring 187. In some embodiments, the second coolant channels 252 are fluidly independent from the first coolant channels 242 to advantageously to cool the edge ring 210 and substrate 122 independently. In some embodiments, the first coolant channels 242 may be fluidly coupled to the second coolant channels 252 so that, for example, coolant flows through an inlet to the first coolant channels 242, then from the first coolant channels 242 to the second coolant channels 252, and then out from one of the second coolant channels. The first coolant channels 242 and the second coolant channels 252 are coupled to a chiller 272 configured to recirculate a coolant therethrough.

In some embodiments, a bonding layer 262 is disposed between the ceramic ring 187 and the second cooling plate 218. In some embodiments, the bonding layer 262 is similar to bonding layer 230. In some embodiments, the bonding layer 262 provides a thermal interface. For example, the bonding layer 262 may be made from a material having a thermal coefficient of about 0.5 to about 10 W/mK). In some embodiments, a second o-ring 265 is disposed between the ceramic ring 187 and the second cooling plate 218 to provide a seal to reduce or prevent backside gas leakage therebetween.

In some embodiments, as shown in FIG. 2, the first cooling plate 208 has a disk shape and is disposed on the second cooling plate 218 having a disk shape. In some embodiments, the second cooling plate 218 has a raised lip 284 at a peripheral edge of the second cooling plate 218 that extends around the first cooling plate 208. In some embodiments, a width of the raised lip 284 is substantially the same as a width of the ceramic ring 187. The raised lip 284 is spaced from the first cooling plate 208 to provide thermal isolation from the first cooling plate 208. The second cooling plate 218 may rest on an insulator plate 248. In some embodiments, one or more fasteners 278 extend through the insulator plate 248, the second cooling plate 218, and partially into the ceramic ring 187 to couple the components together. The ceramic ring 187 coupled to the second cooling plate 218 via the one or more fasteners 278 advantageously allows for a greater allowable temperature difference therebetween. In some embodiments, a third o-ring 255 is disposed between the insulator plate 248 and the second cooling plate 218 to provide a seal therebetween. In some embodiments, the third o-ring 255 is disposed at an outer peripheral edge of the second cooling plate 218. In some embodiments, an outer surface of the ceramic ring 187 is coplanar with an outer surface of the second cooling plate 218.

In some embodiments, as shown in FIG. 2, a thermal isolation layer 282 is disposed between the first cooling plate 208 and the second cooling plate 218 to thermally isolate the first cooling plate 208 from the second cooling plate 218. In some embodiments, the thermal isolation layer 282 is made of CIRLEX®, manufactured by DuPont Electronics, Inc. in Midland, MI. In some embodiments, the thermal isolation layer 282 has a thickness is about 1.0 mm to about 2.0 mm. In some embodiments, the thermal isolation layer 282 has a thermal conductivity of about 0.1 W/mK to about 0.3 W/mK.

FIG. 3 depicts a schematic cross-sectional side view of a ceramic ring 187 in accordance with at least some embodiments of the present disclosure. In some embodiments, the ceramic ring 187 includes a notch 320 on an upper interior edge thereof to accommodate the ceramic plate 152. In some embodiments, the one or more chucking electrodes 228 that are disposed in the ceramic ring 187 comprise a lower electrode 304, an upper electrode 302, and a plurality of posts 310 that extend therebetween to couple the lower electrode 304 to the upper electrode 302. The plurality of posts 310 may comprise about 3 to about 8 posts. In some embodiments, a distance 312 between the lower electrode 304 and the second side 226, or lower side, of the ceramic ring 187 is less than about 2.5 mm. In some embodiments, a second distance 314 between the upper electrode 302 and the first side 244, or upper side, of the ceramic ring 187 is less than about 2.5 mm. Such an arrangement may advantageously reduce or prevent arcing, as well as improve a sheath profile above the ceramic ring 187. In some embodiments, as shown in FIG. 3, the one or more chucking electrodes 228 form indirect electrical contact via capacitive coupling with the second cooling plate 218.

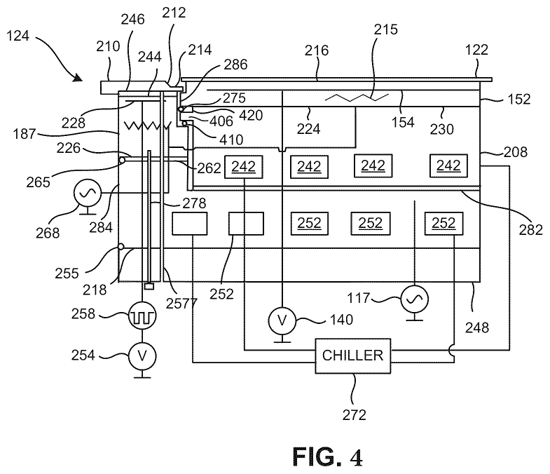

FIG. 4 depicts a schematic partial side view of a substrate support 124 in accordance with at least some embodiments of the present disclosure. In some embodiments, the first cooling plate 208 includes an outer ring 406 that at least partially defines an upper peripheral notch 420 of the first cooling plate 208. In some embodiments, the o-ring 275 is at least partially disposed in the upper peripheral notch 420 to provide a seal between the first cooling plate 208 and the ceramic plate 152 to, for example, protect the bonding layer 230 from plasma. In some embodiments, the o-ring 275 is disposed adjacent the ceramic ring 187 and the ceramic plate 152 and provides a seal between the first cooling plate 208, the ceramic plate 152, and the ceramic ring 187 to seal the gap between the ceramic ring 187 and the first cooling plate 208 to advantageously reduce or prevent arcing in the gap. In some embodiments, a third o-ring 410 may be disposed between a lower surface of the outer ring 406 and the ceramic ring 187 to provide an additional seal to protect against plasma entering the gap between the ceramic ring 187 and the first cooling plate 208.

While the foregoing is directed to embodiments of the present disclosure, other and further embodiments of the disclosure may be devised without departing from the basic scope thereof.

1. A substrate support, comprising:
a ceramic plate having a first side configured to support a substrate and a second side opposite the first side, wherein the ceramic plate includes an electrode embedded in the ceramic plate;
a first cooling plate coupled to the second side of the ceramic plate;
a ceramic ring disposed about the ceramic plate and having a first side and a second side opposite the first side, wherein the ceramic ring includes one or more chucking electrodes and a heating element disposed in the ceramic ring, wherein the ceramic ring is spaced apart from the ceramic plate and the first cooling plate;
a second cooling plate coupled to the second side of the ceramic ring, wherein the second cooling plate is thermally isolated from the first cooling plate, wherein the first cooling plate and the second cooling plate include coolant channels configured to circulate a coolant; and
a sealing element disposed adjacent to the ceramic ring and the ceramic plate.

2. The substrate support of claim 1, further comprising an edge ring disposed on the ceramic ring and a thermal pad disposed between the edge ring and the ceramic ring.

3. The substrate support of claim 1, further comprising a heater disposed in the ceramic plate.

4. The substrate support of claim 1, wherein the ceramic ring comprises aluminum nitride (AlN) or aluminum oxide (Al₂O₃).

5. The substrate support of claim 1, wherein the ceramic ring includes a notch at an upper interior edge.

6. The substrate support of claim 1, wherein the ceramic plate includes an annular ring and the sealing element between the ceramic ring and the ceramic plate is disposed between a lower surface of the annular ring and the ceramic ring.

7. The substrate support of claim 1, further comprising a bonding layer disposed between the ceramic ring and the second cooling plate.

8. The substrate support of claim 7, wherein the bonding layer is made from a material having a thermal coefficient of about 0.5 to about 10 w/mK.

9. The substrate support of claim 1, wherein the second cooling plate and the ceramic ring are coupled together via one or more fasteners.

10. A substrate support, comprising:
a ceramic plate having a first side configured to support a substrate and a second side opposite the first side, wherein the ceramic plate includes an electrode embedded in the ceramic plate;
a first cooling plate coupled to the second side of the ceramic plate;
a ceramic ring disposed about the ceramic plate and having a first side and a second side opposite the first side, wherein the ceramic ring includes one or more chucking electrodes and a heating element disposed in the ceramic ring, wherein the ceramic ring is spaced apart from the ceramic plate and the first cooling plate;
a second cooling plate coupled to the second side of the ceramic ring, wherein the second cooling plate is thermally isolated from the first cooling plate, wherein the first cooling plate and the second cooling plate include coolant channels configured to circulate a coolant;
one or more sealing elements disposed adjacent to:
the ceramic ring and the second cooling plate; and
the ceramic ring and the ceramic plate; and
an edge ring disposed on the ceramic ring and a thermal pad disposed between the edge ring and the ceramic ring.

11. The substrate support of claim 10, wherein coolant channels of the first cooling plate are fluidly coupled to coolant channels of the second cooling plate.

12. The substrate support of claim 10, wherein the one or more chucking electrodes of the ceramic ring include a lower electrode, an upper electrode, and one or more posts that couple the lower electrode to the upper electrode.

13. The substrate support of claim 10, wherein the first cooling plate is disposed on the second cooling plate with a thermal isolation layer therebetween.

14. The substrate support of claim 10, wherein the second cooling plate has a raised lip at a peripheral edge of the second cooling plate that extends around the first cooling plate.

15. The substrate support of claim 10, wherein an outer surface of the ceramic ring is coplanar with an outer surface of the second cooling plate.

16. A process chamber, comprising:
a chamber body having a substrate support disposed within an inner volume of the chamber body, wherein the substrate support includes a ceramic plate having a first side configured to support a substrate and a second side opposite the first side, wherein the ceramic plate includes an electrode embedded in the ceramic plate;
a first cooling plate coupled to the second side of the ceramic plate;
a ceramic ring disposed about the ceramic plate and having a first side and a second side opposite the first side, wherein the ceramic ring includes one or more chucking electrodes and a heating element disposed in the ceramic ring, wherein the ceramic ring is spaced apart from the ceramic plate and the first cooling plate;
a second cooling plate coupled to the second side of the ceramic ring, wherein the second cooling plate is thermally isolated from the first cooling plate, wherein the first cooling plate and the second cooling plate include coolant channels configured to circulate a coolant; and
a sealing element disposed adjacent to the ceramic ring and the ceramic plate.

17. The process chamber of claim 16, further comprising an edge ring disposed on the ceramic ring and a thermal pad disposed between the edge ring and the ceramic ring.

18. The process chamber of claim 16, wherein the first cooling plate and the second cooling plate are disposed on an insulator.

19. The process chamber of claim 18, further comprising an o-ring disposed between the ceramic ring and the second cooling plate, and a second o-ring disposed between the insulator and the second cooling plate.

20. The process chamber of claim 16, wherein the first cooling plate is disposed on the second cooling plate with a thermal isolation layer therebetween.
